(19) United States
(12) Patent Application Publication
(10) Pub. No.: US 2015/0163969 A1
(43) Pub. Date: Jun. 11, 2015

(54) ELECTRONIC COMPONENT MOUNTING SYSTEM AND ELECTRONIC COMPONENT MOUNTING METHOD

(71) Applicant: Panasonic Intellectual Property Management Co., Ltd., Osaka (JP)

(72) Inventors: Hachiro NAKATSUJI, Yamanashi (JP); Kenji OKAMOTO, Yamanashi (JP)

(21) Appl. No.: 14/561,634

(22) Filed: Dec. 5, 2014

(30) Foreign Application Priority Data
Dec. 6, 2013 (JP) 2013-252645

(51) Int. Cl. H05K 13/04; B23K 1/20; B23K 3/06; B23K 1/00

(52) U.S. Cl. CPC H05K 13/0465; B23K 1/0016; B23K 1/20; B23K 3/0638

(57) ABSTRACT

An electronic component mounting system includes a screen printing apparatus, a coating unit and an electronic component mounting apparatus. The screen printing apparatus supplies a solder paste to a plurality of first lands among lands of a board, using a mask plate including pattern holes formed so as to correspond to the plurality of first lands. The coating unit includes a discharge port for discharging the solder paste, and coats the solder paste through the discharge port on a plurality of second lands other than the plurality of first lands on the board to which the solder paste is supplied through the screen printing apparatus. The electronic component mounting apparatus mounts the electronic components on the first and second lands to which the solder paste is supplied through the screen printing apparatus and the coating unit.

### CROSS REFERENCE TO RELATED APPLICATIONS

This application is based upon and claims the benefit of priority of Japanese Patent Application No. 2013-252645 filed on Dec. 6, 2013, the contents of which are incorporated herein by reference in its entirety.

### BACKGROUND OF THE INVENTION

1. Field of the Invention

The present invention relates to an electronic component mounting method and an electronic component mounting system of mounting electronic components on lands provided on a board using a solder paste.

2. Description of the Related Art

In an electronic component mounting step, screen printing is used as a method of supplying a solder paste to lands provided on a board. In this method, a mask plate provided with pattern holes corresponding to the lands is brought into contact with the board, the solder paste is supplied onto the mask plate, a squeegee is slid against the mask plate, and thereby the solder paste is printed on the board via the pattern holes. The board having the solder paste printed thereonto is sent to a subsequent electronic component mounting step, and electronic components are mounted on the board.

In a surface mounting method used in recent years, electronic components having considerably different sizes may be mounted on the board, and the range of the electronic components is from tiny chip components of a 0402 size or the like to large components such as a relatively large chip electrolytic capacitor or a power electronic component. The sizes of the lands provided on the board become considerably different depending on the type and size of electronic components, and the necessary amounts of a solder become extremely different depending on the sizes of the lands. In typical screen printing, the solder paste is printed on the lands, using a single mask plate with a uniform thickness, but when the necessary amounts of a solder are extremely different, it is considerably difficult to perform the screen printing using the single mask plate with the uniform thickness. For this reason, proposed is a paste printing method of using mask plates with different thicknesses for a region in which the fine lands are highly densely mounted, and a region in which the fine lands are not highly densely mounted (for example, refer to JP-A-5-212852 and JP-A-2005-138341).

In an example illustrated in JP-A-5-212852, a first step is performed in which the paste is printed on the board, using a first mask plate with a small thickness, and then a second step is performed in which the paste is printed on the board, using a second mask plate with a large thickness. A concave portion is provided on a back surface of the second mask plate, and is positioned to correspond to the paste printed on the board in the first step, and when the second step is performed, paste portions formed on the lands in the first step can be prevented from interfering with the second mask plate.

In an example illustrated in JP-A-2005-138341, the mask plate is provided with a stepped portion in which the thickness is changed, and a plurality of pattern holes are formed in the mask plate, the thickness of which is changed, and are positioned to correspond to the lands on the board. Since the screen printing is performed using the mask plate with this shape, it is possible to form the paste portions having different thicknesses on the lands at the same time, and improve productivity.

### SUMMARY OF THE INVENTION

However, in the example illustrated in JP-A-5-212852, there is a problem in having to prepare two pieces of mask plates with different thicknesses. There is a problem in that when the positioning error of the printing occurs in the first step, it is difficult to prevent the paste portions formed on the lands from interfering with the second mask plate depending on a degree of the positioning error, and thus the screen printing has a very high degree of difficulty. Since it is necessary to secure the rigidity of the second mask plate, in a design stage of the board, there are certain limitations to the number of lands or the disposition of the lands which become printing targets in the first step.

There is a problem in that the mask plate disclosed in JP-A-2005-138341 has the stepped portion in which the thickness is changed, and printing failure is likely to occur in the vicinity of the stepped portion. Accordingly, the board has a design limitation that it is not possible to form the lands in a region which is expected to be the vicinity of the stepped portion of the mask plate, and due to this limitation, it is not possible to dispose the electronic components at high density.

A non-limited object of the present invention is to provide an electronic component mounting method and an electronic component mounting system by which it is possible to solve the problems.

An aspect of the present invention provides an electronic component mounting method of using a solder paste to mount electronic components on a plurality of lands provided on a board, the method including: supplying the solder paste to a plurality of first lands via screen printing among the plurality of lands, using a mask plate including pattern holes formed so as to correspond to the plurality of first lands; supplying the solder paste to a plurality of second lands other than the first lands among the plurality of lands, using a coating unit provided with a discharge port for discharging the solder paste; and mounting the electronic components on the first and second lands to which the solder paste is supplied.

Another aspect of the present invention provides an electronic component mounting system of using a solder paste to mount electronic components on a plurality of lands provided on a board, the system including: a screen printing apparatus that supplies the solder paste to a plurality of first lands among the plurality of lands, using a mask plate including pattern holes formed so as to correspond to the plurality of first lands; a coating unit which includes a discharge port for discharging the solder paste, and coats the solder paste through the discharge port on a plurality of second lands other than the plurality of first lands on the board to which the solder paste is supplied through the screen printing apparatus; and an electronic component mounting apparatus that mounts the electronic components on the first and second lands to which the solder paste is supplied through the screen printing apparatus and the coating unit.

According to the aspects of the present invention, it is possible to mount electronic components at high density and with high quality.

### BRIEF DESCRIPTION OF THE DRAWINGS

In the accompanying drawings:

FIG. 1 is an entire configuration view of an electronic component mounting system according to an embodiment of the present invention;

FIG. 2 is a front view of a screen printing apparatus of the electronic component mounting system according to the embodiment of the present invention;

FIGS. 3A and 3B illustrate plan views of the screen printing apparatus of the electronic component mounting system according to the embodiment of the present invention;

FIG. 4 is a plan view of a solder coating apparatus of the electronic component mounting system according to the embodiment of the present invention;

FIG. 5 is a diagram illustrating the structure of a dispenser provided in the solder coating apparatus of the electronic component mounting system according to the embodiment of the present invention;

FIG. 6 is a plan view of an electronic component mounting apparatus of the electronic component mounting system according to the embodiment of the present invention;

FIG. 7 is a flowchart of electronic component mounting steps according to the embodiment of the present invention;

FIGS. 8A to 8G are diagrams illustrating the electronic component mounting steps according to the embodiment of the present invention;

FIG. 9 is a flowchart of sorting process of lands according to the embodiment of the present invention;

FIG. 10 is a diagram illustrating a temporary land determination screen according to the embodiment of the present invention; and

FIG. 11 is a diagram illustrating a production cycle display screen according to the embodiment of the present invention.

### DETAILED DESCRIPTION OF THE EXEMPLARY EMBODIMENTS

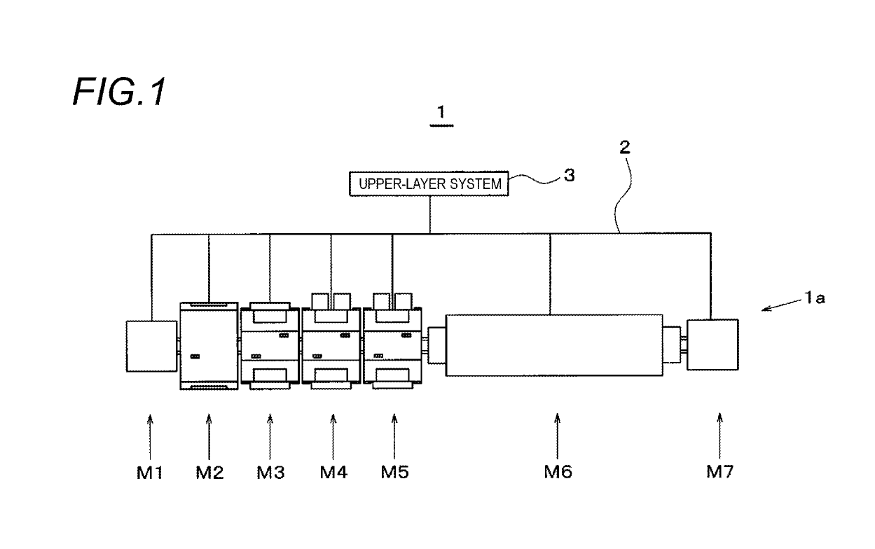

First, an electronic component mounting system according to an embodiment of the present invention will be described with reference to FIG. 1. An electronic component mounting system 1 serves to mount electronic components using a solder paste (a paste obtained by mixing solder particles and flux, and hereinafter, simply referred to as a “solder”) for bonding the components to lands (electrodes) provided on a board. The electronic component mounting system 1 includes an electronic component mounting line la as a main body in which a plurality of component mounting apparatuses are connected in series to each other in an X direction (board transportation direction), and the component mounting apparatuses include a board supply apparatus M1; a screen printing apparatus M2; a solder coating apparatus M3; a first electronic component mounting apparatus M4; a second electronic component mounting apparatus M5; a reflow apparatus M6; and a board collection apparatus M7. Each of the component mounting apparatuses M1 to M7 are connected to an upper layer system 3 via a communication network 2 such as a local area network, and the upper layer system 3 has a management computer.

The board supply apparatus M1 supplies a board on which the electronic components are to be mounted. The screen printing apparatus M2 supplies the solder to predetermined lands of a plurality of the lands provided on the board via screen printing. The solder coating apparatus M3 supplies the solder to lands to which the solder is supplied through the screen printing apparatus M2, via coating using a dispenser that will be described later. The first electronic component mounting apparatus M4 and the second electronic component mounting apparatus M5 mount the electronic components on the board to which the solder is supplied. The reflow apparatus M6 melts and solidifies the solder by heating the board with the electronic components mounted thereonto per a predetermined heating profile. Accordingly, it is possible to complete a mounted board onto which the electronic components are solder-bonded. The board collection apparatus M7 collects the mounted board.

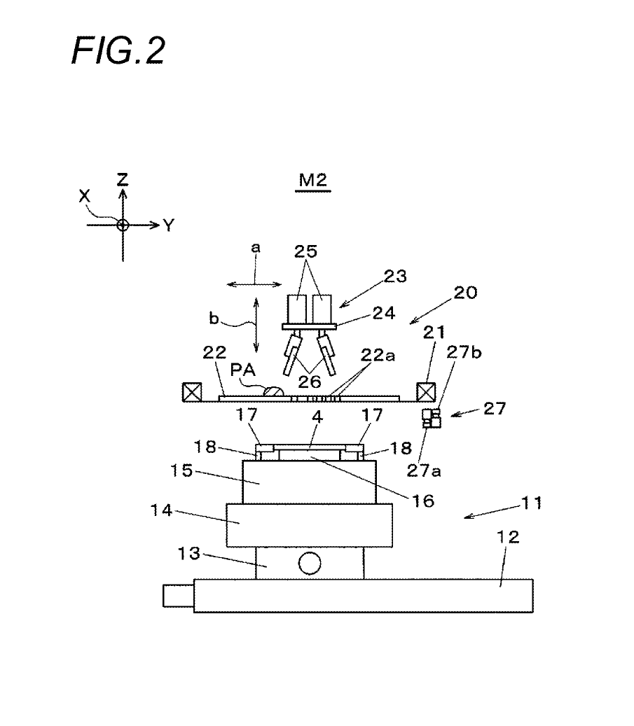

Subsequently, the screen printing apparatus M2 will be described with reference to FIG. 2. The screen printing apparatus M2 has a configuration in which a screen printing unit 20 is provided above a board positioning unit 11. The board positioning unit 11 serves to hold a board 4 supplied from an upstream apparatus, and locates the board 4 at a predetermined printing position, and has a configuration in which a Y-axis table 12, an X-axis table 13, and an θ-axis table 14 are stacked on each other, and a Z-axis table 15 is installed thereon. A board support unit 16 is provided on the Z-axis table 15 so as to receive the board 4 and support a lower surface of the board 4.

A pair of transportation conveyors 18 are provided above the board positioning unit 11 in the X direction. Clamps 17 are respectively provided on the transportation conveyors 18 so as to be movable in the X direction and a Y direction orthogonal to the X direction in a horizontal plane. The board 4 is transported onto the board support unit 16 from an upstream side by the transportation conveyors 18, and is interposed between the clamps 17, and the position of the board 4 is fixed. The board support unit 16 and the clamps 17 form a board holding unit for holding the board 4. The driving of the Z-axis table 15 moves the transportation conveyors 18, the clamps 17, and the board support unit 16 up and down in a vertical direction (Z direction) together with the board 4 held.

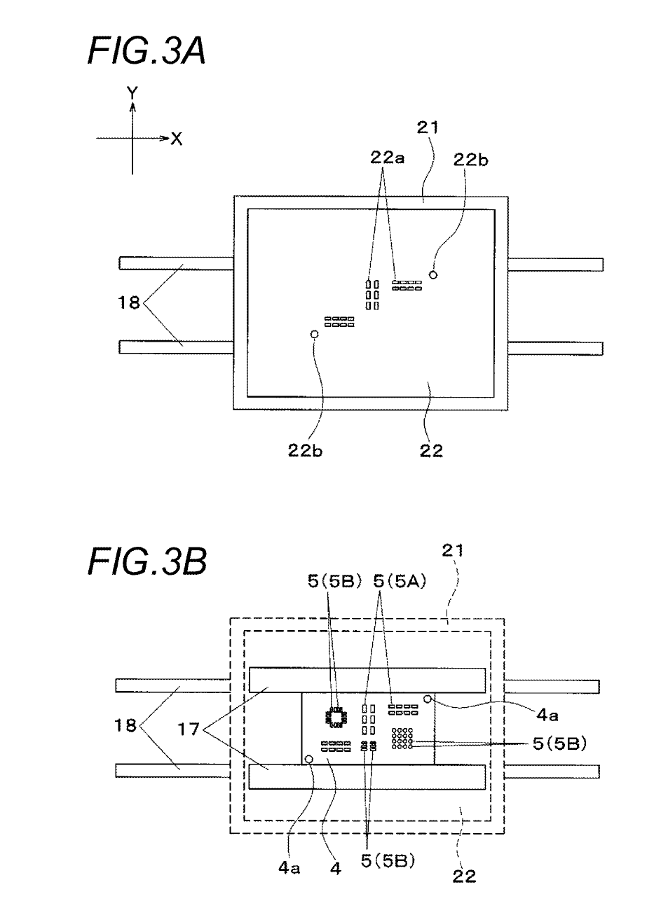

The screen printing unit 20 includes a mask plate 22 deployed in a mask frame 21. As shown in FIG. 3A, the mask plate 22 is provided with a plurality of pattern holes 22a. In FIG. 3B, the pattern hole 22a are provided so as to correspond to shapes and positions of particular lands 5 provided in the board 4, respectively. The solder PA (FIG. 2) is supplied on the mask plate 22 by a syringe (not illustrated) for solder supply.

Here, the relation between the area of the land 5 and the supply amount of the solder PA will be described. The plurality of lands 5 provided in the board 4 vary in area depending on the kind or size of the electronic components to be mounted, or the like. In general, the amount of supply of the solder PA is increased as the area of the land 5 is larger.

As shown in FIG. 3B, the plurality of lands 5, which are different in area, are provided in the board 4 as a mounting target in the embodiment. The pattern holes 22a are provided so as to correspond to shapes and positions of a plurality of first lands 5A which have relatively large areas, among the plurality of lands 5 provided in the board 4. On the other hand, the pattern holes 22a are not provided to correspond to a plurality of second lands 5B other than the first lands 5A among the plurality of lands 5. The second lands 5B have relatively small areas. Accordingly, the screen printing apparatus M2 supplies the solder PA on the first lands 5A.

In FIG. 2, a printing head 23 equipped with squeegees 26 is provided above the mask plate 22. The printing head 23 has a configuration in which a squeegee lifting mechanism 25 for lifting the squeegees 26 up and down is provided on a moving base 24 that is movable in the Y direction. A squeegee moving mechanism (not illustrated) moves the printing head 23 horizontally and in the Y direction (along an arrow a). The squeegee lifting mechanism 25 is driven to lift the squeegees 26 up and down (along an arrow b) and bring the squeegees 26 into contact with an upper surface of the mask plate 22.

In the screen printing, the Z-axis table 15 is driven to lift the board 4 up and bring the board 4 into contact with a lower surface of the mask plate 22. The squeegee moving mechanism is driven to perform a squeegeeing operation of moving the squeegees 26 against the upper surface of the mask plate 22 in the Y direction, the solder PA being supplied to the upper surface of the mask plate 22. Accordingly, the solder PA is screen printed on the board via the pattern holes 22a.

In FIG. 2, a camera head unit 27 is provided below the mask plate 22 and is horizontally movable. The camera head unit 27 includes a board identification camera 27a and a mask identification camera 27b. The board identification camera 27a captures an image of a board identification mark 4a (refer to FIG. 3B) from above, and the board identification mark 4a is formed on each corner portion on a diagonal line of the board 4. The mask identification camera 27b captures an image of mask identification marks 22b (refer to FIG. 3A) from below, and the mask identification marks 22b are formed on the mask plate 22, and positioned to correspond to the board identification marks 4a, respectively. The movement of the camera head unit 27 allows the board identification camera 27a and the mask identification camera 27b to move to a position that corresponds to the positions of the board identification mark 4a and the mask identification mark 22b, and to capture the images of the board identification mark 4a and the mask identification mark 22b, respectively. The captured images are sent to a process unit that is not illustrated, and the process unit performs an identification process of the board identification mark 4a and the mask identification mark 22b. The board positioning unit 11 moves the board 4 held by the board holding unit, based on a result of the identification process, and thus aligns the board 4 and the mask plate 22 with each other in a horizontal plane.

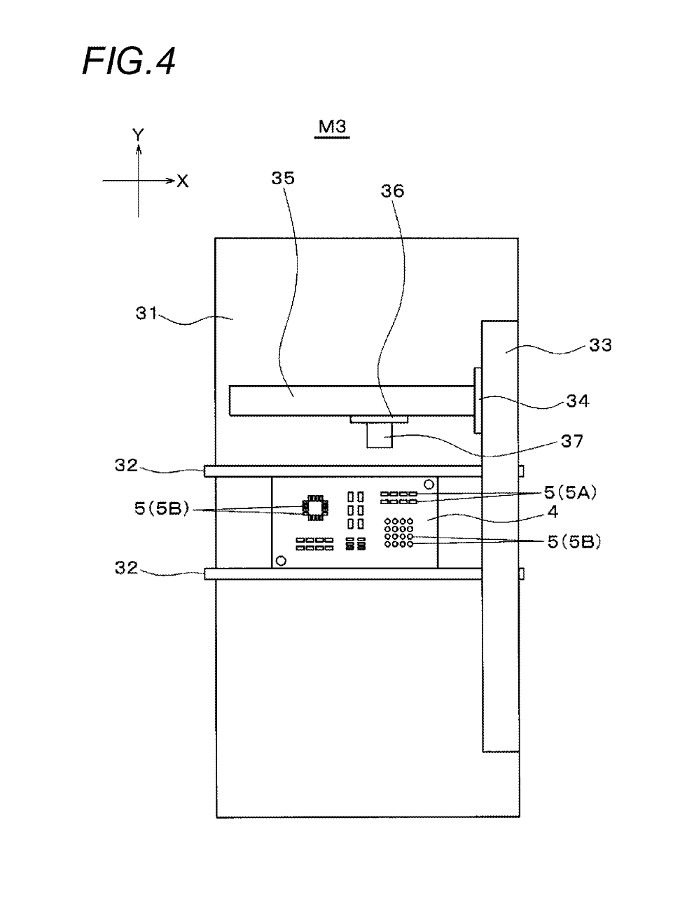

Subsequently, the solder coating apparatus M3 will be described with reference to FIG. 4. A pair of transportation conveyors 32 are provided on a base 31 in the X direction. The transportation conveyors 32 receive the board 4 from the upstream screen printing apparatus M2, transport the board 4 to a predetermined coating operation position, and locate the board 4 at the predetermined coating operation position. A Y-axis table 33 having a linear drive mechanism is provided in one end portion of the base 31 in the X direction, and is horizontal in the Y direction. A joint bracket 34 is installed on the Y-axis table 33, and slidable in the Y direction. An X-axis table 35 is joined to the joint bracket 34, and is provided with a linear drive mechanism similar to the Y-axis table 33.

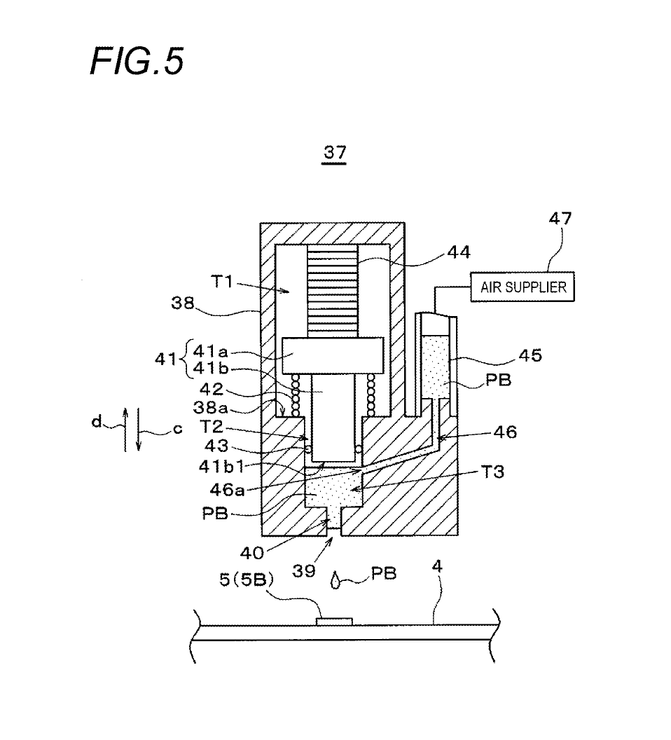

A joint bracket 36 is installed on the X-axis table 35, and slidable in the X direction, and a dispenser 37 is attached to the joint bracket 36. The dispenser 37 serves to supply the solder PB (refer to FIG. 5) to the second lands 5B via an injection method, and the X-axis table 35 and the Y-axis table 33 move the dispenser 37 in the X and Y directions. The Y-axis table 33 and the X-axis table 35 are moving mechanisms to horizontally move the dispenser 37.

The structure of the dispenser 37 will be described with reference to FIG. 5. A main body portion 38 of the dispenser 37 is provided with a first space T1 and a second space T2 that has a length smaller than that of the first space T1 in a lateral direction. The first space T1 vertically communicates with the second space T2. A discharge port 39 is formed in a lower surface of the main body portion 38, and communicates with the second space T2 via a communication path 40.

A T-shaped plunger 41 is provided in the first space T1. The plunger 41 includes a flange portion 41a that extends horizontally, and a shaft portion 41b that extends downward from substantially the center of the flange portion 41a. A spring member 42 is provided between the flange portion 41a and an upper surface 38a of the main body portion 38, and the upper surface 38a forms a lower end of the first space T1. The spring member 42 biases the plunger 41 upward. A part of the shaft portion 41b of the plunger 41 penetrates into the second space T2, the part of the shaft portion 41b including a lower end portion 41b1 thereof, and a third space T3 is formed below the shaft portion 41b.

In the second space T2, a ring-shaped sealing member 43 is provided in a gap between an outer circumferential surface of the shaft portion 41b and an inner surface of the main body portion 38 which faces the outer circumferential surface. The sealing member 43 blocks the solder PB that is pushed upward when pressure is applied to a compression chamber (to be described later), and serves to prevent the solder PB from flowing into the first space T1.

Laminated voltage elements 44 are provided on an upper surface of the flange portion 41a, and is made by laminating a plurality of voltage elements in the vertical direction. The laminated voltage elements 44 are displaced in a laminating direction of the voltage elements when voltage is applied thereto. Accordingly, the plunger 41 moves downward (along an arrow c) against an upward biasing force caused by the spring member 42, and thus a predetermined pressure is applied to the third space T3. As such, the third space T3 functions as the compression chamber. When a voltage is not applied to the laminated voltage elements 44, the plunger 41 is biased and moved upward (along an arrow d) by the spring member 42.

A solder reservoir unit 45 is provided on a side portion of the main body portion 38, and stores a paste-like solder PB therein. A conduit 46 is provided from a lower surface of the solder reservoir unit 45 to the third space T3 (compression chamber), and the solder PB stored in the solder reservoir unit 45 is supplied to the third space T3 via the conduit 46. When voltage is not applied to the laminated voltage element 44, a connection port 46a between the conduit 46 and the third space T3 is positioned downward of the shaft portion 41b.

The solder reservoir unit 45 is connected to an air supplier 47. When air is supplied to the solder reservoir unit 45 from the air supplier 47, the solder PB is delivered to the conduit 46. Accordingly, the solder PB is supplied to the third space T3, that is, the compression chamber via the conduit 46. The solder PB stored in the solder reservoir unit 45 may be the same as the solder PA used by the screen printing apparatus M2.

When the plunger 41 moves downward in a state where the solder PB is supplied to the compression chamber, the solder PB in the third space T3 is pressurized, and is pushed into the communication path 40, and a lump of the solder PB similar to a droplet is discharged downward from the discharge port 39. Accordingly, the solder PB can be supplied to the second lands 5B that are positioned below the discharge port 39. A very small amount of the solder PB is discharged at a time, and the dispenser 37 adjusts the amount of the solder supplied to the second lands 5B by changing the frequency of discharge. For this reason, the dispenser 37 is suitable for supplying the solder PB in small amounts. The dispenser 37 is a coating unit that includes a discharge port for discharging the solder paste, and coats the solder paste on the plurality of second lands 5B other than the plurality of first lands 5A of the board 4, to which the solder paste is supplied through the screen printing apparatus M2.

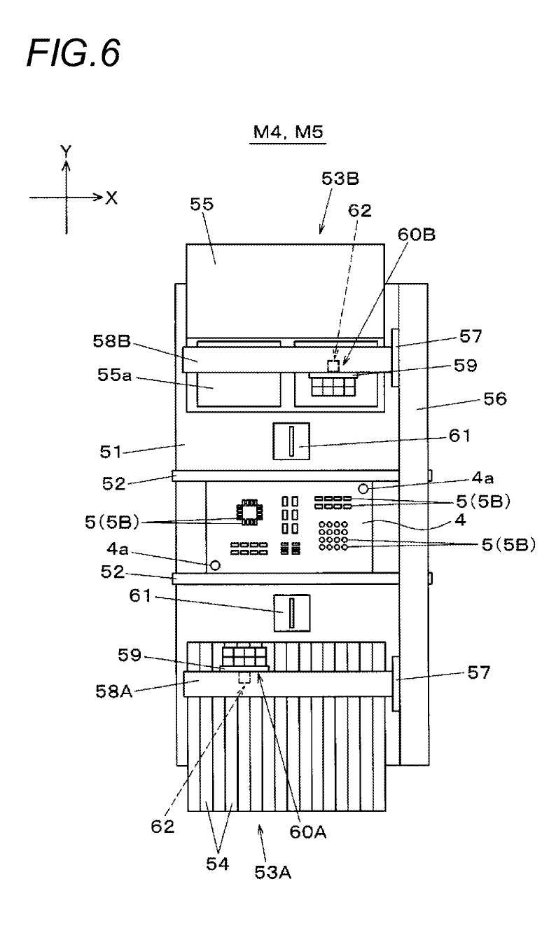

Subsequently, the first electronic component mounting apparatus M4 and the second electronic component mounting apparatus M5 will be described with reference to FIG. 6. The electronic component mounting apparatuses M4 and M5 will be indiscriminately described due to having the same structure. A pair of transportation conveyors 52 are provided on a base 51 in the X direction. After the solder is supplied to the board 4, the transportation conveyors 52 transport the board 4 and locate the board 4 at a predetermined mounting operation position. Component supply units 53A and 53B are provided on opposite sides of the transportation conveyors 52. A plurality of tape feeders 54 are disposed in the component supply unit 53A, and a tray feeder 55 is disposed in the component supply unit 53B.

A carrier tape is installed on the tape feeder 54, and stores small electronic components such as so-called 0402 and 0603 components. The tape feeder 54 supplies the electronic components to a mounting head 60A by pitch-feeding the carrier tape. The tray feeder 55 accommodates a tray 55a in which large electronic components such as a BGA and a GSP are stored in a grid array. The tray feeder 55 supplies the electronic components to a mounting head 60B by moving the tray 55a to a component unloading position at which the electronic components are unloaded by the mounting head 60B.

The type of the feeder disposed in each of the component supply units 53A and 54B is changed depending on the board 4 that is a mounted object. For example, the tape feeders 54 may be disposed in both the component supply unit 53A and 54B. The type or disposition of the feeder may be switched between the first electronic component mounting apparatus M4 and the second electronic component mounting apparatus M5.

A Y-axis table 56 having a linear drive mechanism is provided in one end portion of the base 51 in the X direction, and is horizontal in the Y direction, and two joint brackets 57 are installed on the Y-axis table 56, and slidable in the Y direction. Two X-axis tables 58A and 58B are respectively joined to the joint brackets 57, and each of the X-axis tables 58A and 58B is provided with a linear drive mechanism similar to the Y-axis table 56. Joint brackets 59 are respectively installed on the X-axis tables 58A and 58B, and slidable in the X direction, and the mounting heads 60A and 60B are respectively attached to the joint brackets 59.

A suction nozzle (not illustrated) is installed in a lower end portion of each of the mounting heads 60A and 60B so as to suction and hold the electronic component, and a nozzle lifting mechanism built in each of the mounting heads 60A and 60B lifts the suction nozzle up and down. The X-axis tables 58A and 58B and the Y-axis table 56 move the mounting heads 60A and 60B in the X and Y directions. Accordingly, the mounting head 60A unloads the electronic components from the tape feeder 54, and mounts the electronic components on the board 4. The mounting head 60B unloads the electronic components from the tray feeder 55, and mounts the electronic components on the board 4.

A component identification apparatus 61 is provided between the component supply unit 53A and the transportation conveyor 52, and the component supply unit 53B and the transportation conveyor 52. The component identification apparatus 61 identifies the electronic components by capturing images of the electronic components from below, which are respectively unloaded from the component supply units 53A and 53B and held by the mounting heads 60A and 60B. A board identification camera 62 is attached to each of the mounting heads 60A and 60B. The board identification camera 62 captures an image of the board identification mark 4a of the board 4 at the mounting operation position. The process unit (not illustrated) performs an identification process of the captured image. After positional correction is performed so as to align the mounting heads 60A and 60B with the board 4, based on a detected positional deviation result, the electronic components are mounted on the board 4.

In the embodiment, the first electronic component mounting apparatus M4 includes the two mounting heads 60A and 60B, and when any one of the mounting heads 60A and 60B is replaced with the dispenser 37, the dispenser 37 may be disposed in the first electronic component mounting apparatus M4 in a state where the dispenser 37 is attached to any one of the two joint brackets 59.

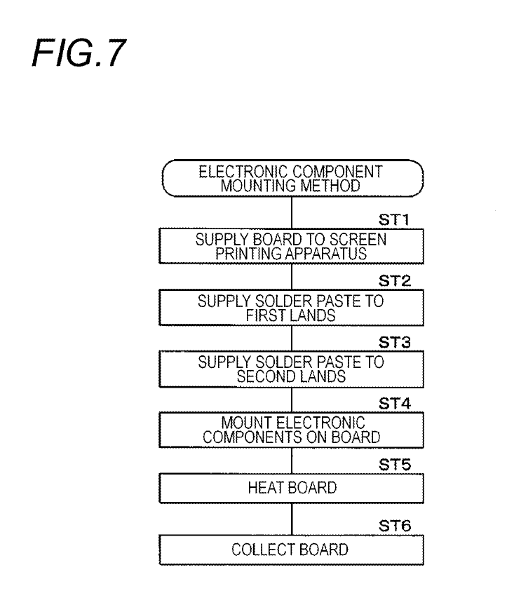

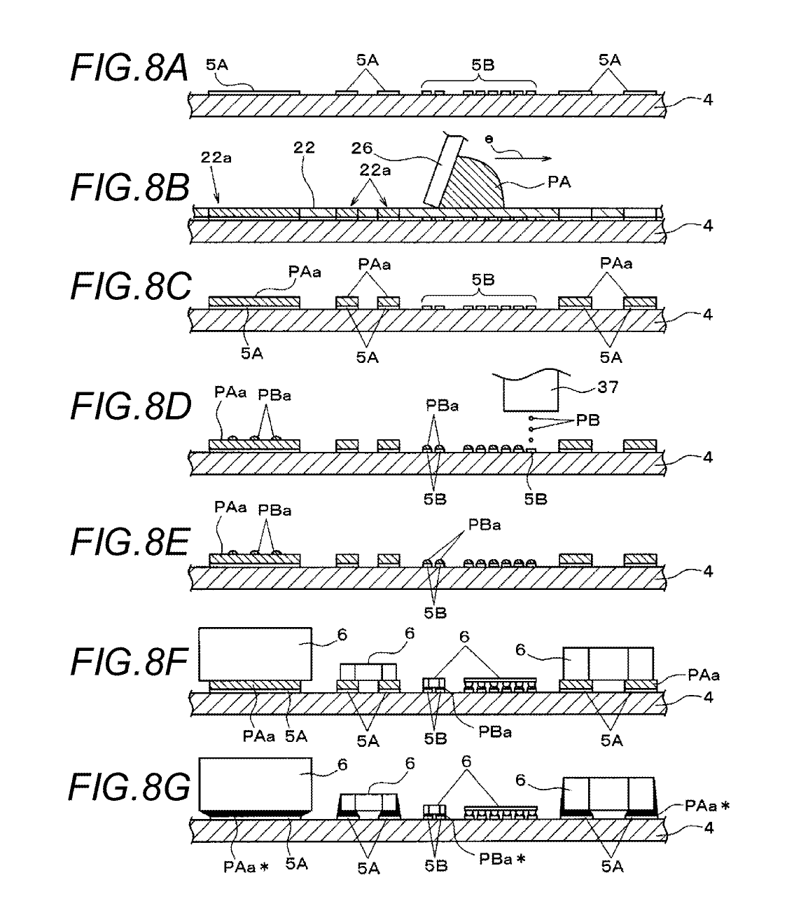

The electronic component mounting system of the embodiment has the above-mentioned configuration, and subsequently, an electronic component mounting method will be described with reference to a flowchart shown in FIG. 7 and step illustrative diagrams shown in FIGS. 8A to 8G. The respective control units (not illustrated) of the component mounting apparatuses M1 to M7 control the respective mechanisms of the component mounting apparatuses M1 to M7 to perform operations that will be described below. As illustrated in FIG. 8A, the board 4 that is a mounting target is provided with the plurality of first lands 5A and the plurality of second lands 5B, each of which has an area smaller than that of the first land 5A. The examples of the second land 5B include a land for soldering very small components such as so-called 0402 and 0608 components, and a land for bonding a bump such as a BGA or a CSP having a bump pitch of 0.3 mm or smaller.

First, the board supply apparatus M1 supplies the board 4 to the screen printing apparatus M2 (step (ST) 1: board supply step). Subsequently, the screen printing apparatus M2 supplies the solder PA to the board 4. That is, as illustrated in FIG. 8B, in a state where the board 4 is in contact with the lower surface of the mask plate 22, the squeegee 26 squeegees the solder PA supplied onto the upper surface of the mask plate 22 (along an arrow e). Accordingly, as illustrated in FIG. 8C, the solder PA is screen-printed on the board 4, and solder portions PAa have the same thickness are respectively formed on the plurality of first lands 5A via the pattern holes 22a.

Here, since the mask plate 22 is not provided with the pattern holes 22a that are positioned so as to correspond to the second lands 5B, the solder PA is not supplied to the second lands 5B. As such, the screen printing apparatus M2 supplies the solder paste to the plurality of first lands 5A via screen printing, using the mask plate 22 in which the pattern holes 22a are provided so as to correspond to the plurality of first lands 5A among the plurality of lands 5, each of the first lands 5A having a relatively large area (ST2: first solder paste supply step).

After the operation of the screen printing apparatus M2 for the board 4 is complete, the board 4 is transported to the solder coating apparatus M3. Subsequently, the solder coating apparatus M3 supplies the solder PB to the board 4. That is, as illustrated in FIG. 8D, when the board 4 is located at the coating operation position, the dispenser 37 moves to a position above each of the second lands 5B that is a target for the supply of the solder PB. Subsequently, the dispenser 37 supplies a predetermined amount of the solder PB to the second lands 5B by discharging the solder PB via the discharge port 39. Accordingly, as illustrated in FIG. 8E, solder portions PBa are respectively formed on the second lands 5B. Thereafter, the dispenser 37 moves to a position above each of the other second lands 5B to which the solder is not supplied, and supplies the solder PB to the relevant second lands 5B in the above-mentioned manner. Until the solder PB is supplied to all of the second lands 5B, the dispenser 37 repeatedly supplies the solder PB to the second lands 5B.

As such, the solder coating apparatus M3 supplies the solder paste to the plurality of second lands 5B but not to the first lands 5A among the plurality of lands 5, using the coating unit provided with the discharge port 39 for the discharge of the solder paste (ST3: second solder paste supply step). The solders PA and PB are supplied to all of the lands 5A and 5B via the above-mentioned steps. When the first lands 5A to which the solder is insufficiently supplied even with the use of a screen printing method are present, the dispenser 37 may move to a position above each of the relevant first lands 5A, and supplementarily coat the corresponding solder portions PAa with the solder PB by a shortfall of the solder. Accordingly, as illustrated in FIGS. 8D and 8E, the solder portion PBa is formed on an upper surface of each of the solder portions PAa, and thus it is possible to compensate for a deficiency in the supply of the solder PA to the first lands 5A.

After the operation of the solder coating apparatus M3 for the board 4 is complete, the board 4 is transported to the first electronic component mounting apparatus M4. Subsequently, the first electronic component mounting apparatus M4 mounts the electronic components on the board 4. That is, as illustrated in FIG. 8F, when the board 4 is located at the mounting operation position, the mounting heads 60A and 60B unload electronic components 6 from the tape feeder 54 or the tray feeder 55, and mount the electronic components 6 on the predetermined lands 5 (5A, 5B). After the operation of the first electronic component mounting apparatus M4 for the board 4 is complete, the board 4 is transported to the second electronic component mounting apparatus M5, and the electronic components are mounted on the board 4 in the above-mentioned manner. As such, the first electronic component mounting apparatus M4 and the second electronic component mounting apparatus M5 mount the electronic components 6 on the first lands 5A and the second lands 5B to which the solder paste is supplied through the screen printing apparatus M2 and the coating unit (ST4: electronic component mounting step).

Subsequently, the board 4 with the electronic components mounted thereonto is transported to the reflow apparatus M6. The reflow apparatus

M6 heats the transported board 4 per a predetermined heating profile (ST5: board heating step). Accordingly, as illustrated in FIG. 8G, the solder portions PAa and PBa are melted and solidified, and solder bonding portions PAa* and PBa* are respectively formed between the electronic components 6 and the lands 5A and 5B. A mounted board is completed via the above-mentioned steps. Thereafter, the mounted board is collected by the board collection apparatus M7 (ST6: board collection step).

As described above, in the embodiment, the solder PA is supplied to the first land 5A having a relatively large area via the screen printing, and the solder PB is supplied to the second land 5B having a relatively small area via the dispenser 37. Accordingly, it is possible to mount the electronic components 6 of various types or sizes on a piece of the board 4 at high density and with high quality. In a design stage of the board, it is possible to improve the degree of freedom in the number of lands 5 or the dispositional positions of the lands 5.

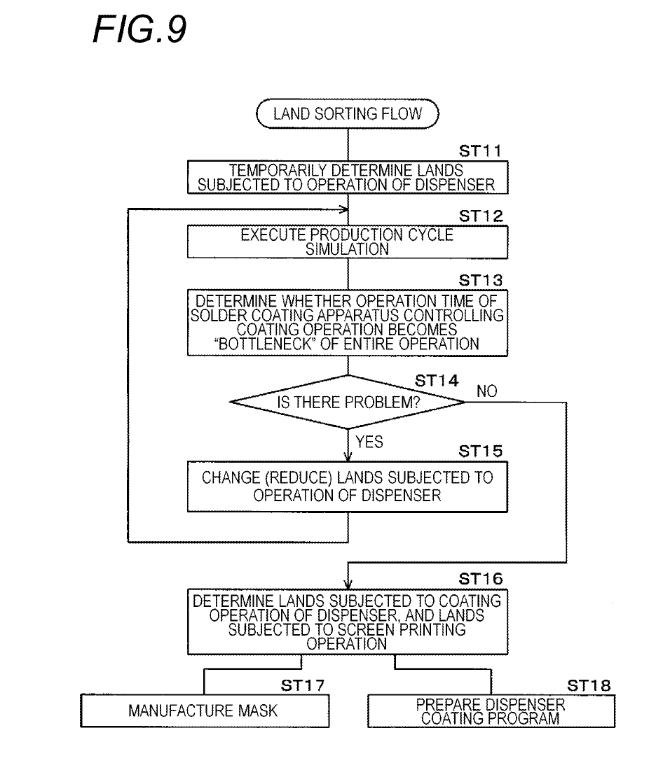

Subsequently, a sorting operation for the lands will be described with reference to a flowchart in FIG. 9, which is an operation of sorting the first land 5A to which the solder PA is supplied via the screen printing, and the second land 5b to which the solder PB is supplied via the dispenser 37. A process apparatus such as a workstation, a personal computer, or a CAD used when designing the mask plate is used in step ST12 and ST13 among operations to be described below.

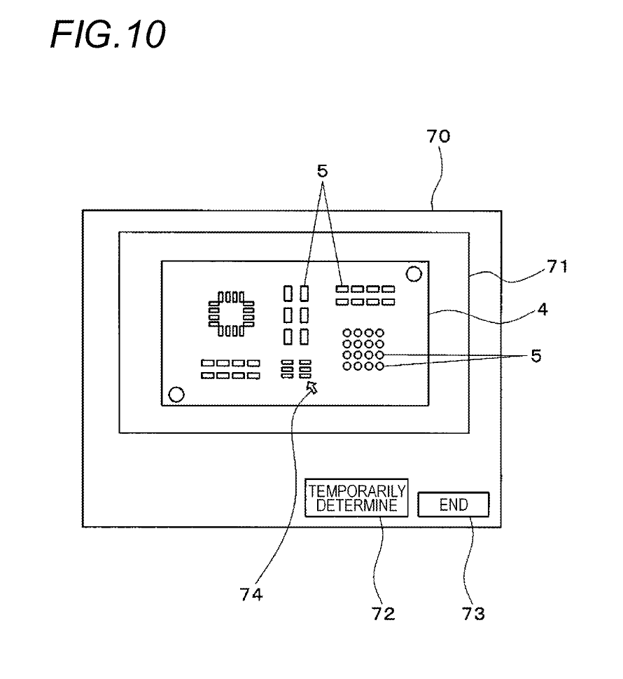

First, for the plurality of lands 5 provided on the board 4, an operator temporarily determines the lands 5 subjected to the operation of the dispenser 37 (ST11: temporary land determination step). That is, in this step, the lands 5, to which the solder PB is supplied via the dispenser 37, are temporarily determined. Accordingly, the lands 5, to which the solder PA is supplied via the screen printing, are automatically and temporarily determined. FIG. 10 illustrates a temporary land determination screen 70 that is displayed on a display unit of the process apparatus so as to temporarily determine the lands 5 subjected to the operation of the dispenser 37.

In FIG. 10, the temporary land determination screen 70 displays a “land display section” 71; a “temporarily determine” switch 72; and an “end” switch 73. The “land display section” 71 displays the images of the board 4 and the entirety of the lands 5 provided on the board 4. The “temporarily determine” switch 72 is an operation switch for temporarily determining the lands 5 selected from the “land display section” 71 as targets for the operation of the dispenser 37, and other lands 5 as targets for the operation of the screen printing apparatus M2. The “end” switch 73 is an operation switch for turning off the temporary land determination screen 70.

The operator selects the plurality of lands 5, each of which is assumed to have a relatively small area, based on the images of the lands 5 displayed on the “land display section” 71, and pre-acquired information regarding the sizes of the lands 5, the types of the electronic components 6 to be mounted, and the like. A pointer 74 displayed on the temporary land determination screen 70 is moved onto a desired land 5 by the operator, and the operator clicks the desired land 5 at that position. Accordingly, the lands 5 subjected to the operation of the dispenser 37 are selected. In step ST1, the lands 5 subjected to the operation of the screen printing apparatus M2 may be selected.

When the lands 5 subjected to the operation of the dispenser 37 are temporarily determined, the process apparatus executes a production cycle simulation, using an installed production cycle simulation program (ST12; production cycle simulation execution step). Here, the production cycle simulation refers to a process of calculating an operation time required for a piece of the board 4 by each of the component mounting apparatuses M2 to M5. When the operator selects the “temporarily determine” switch 72 on the temporary land determination screen 70, this step starts.

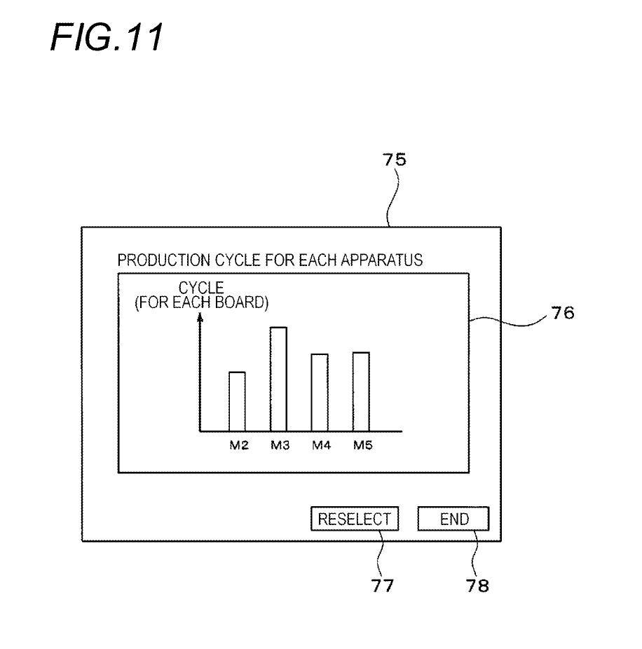

FIG. 11 illustrates a production cycle display screen 75 on which a measured cycle result for each of the component mounting apparatuses M2 to M5 is displayed on the display unit. The production cycle display screen 75 displays a “production cycle display section” 76, a “reselect” switch 77, and an “end” switch 78. The “production cycle display section” 76 displays a bar graph individually illustrating the production cycle required for a piece of the board 4 by each of the component mounting apparatuses M2 to M5. The “reselect” switch 77 is an operation switch for returning to the temporary land determination screen 70, and re-selecting the lands 5 subjected to the operation of the dispenser 37. The “end” switch 78 is an operation switch for turning off the production cycle display screen 75.

The operator confirms whether the operation time of the solder coating apparatus M3 controlling the coating operation becomes the bottleneck of the entire operation, based on the measured production cycle results displayed on the “production cycle display section” 76 (ST13: bottleneck confirmation step). That is, the operator confirms whether the operation time of the solder coating apparatus M3 is significantly longer than that of each of the other component mounting apparatuses M2, M4, and M5.

The operator determines whether the operation time of the solder coating apparatus M3 becomes a problematic bottleneck (ST14: problem existence determination step). For example, the operator determines whether the operation time of the solder coating apparatus M3 is significantly longer than that of each of the other component mounting apparatuses M2, M4, and M5, and thus there is imbalance in the operation time between the apparatuses, and productivity is adversely affected.

When the operator determines that the operation time of the solder coating apparatus M3 becomes a problematic bottleneck (ST14), the operator changes the number of lands 5 that are temporarily determined as the targets for the operation of the dispenser 37 (ST15: land number changing step). Referring to the above-mentioned example, the operator selects the “reselect” switch 77 displayed on the production cycle display screen 75, and displays the temporary land determination screen 70 again. The operator reselects the lands 5 subjected to the operation of the dispenser 37. At this time, the operator sets the number of selected lands 5 which is smaller than the number of lands 5 that are selected when executing the previous production cycle simulation. The operator temporarily re-determines the lands 5 subjected to the operation of the dispenser 37, and the lands 5 subjected to the operation of the screen printing apparatus M2 by selecting the “temporarily determine” switch 72. Thereafter, the process apparatus executes the production cycle simulation again (ST12).

In contrast, when the operator determines that there are no problems in step ST14, the operator formally determines the lands 5 that become the targets for the operation of the dispenser 37, and the lands 5 that become the targets for the operation of the screen printing apparatus M2 (ST16: land determination step). That is, the operator determines the lands 5 temporarily determined as the targets for the operation of the dispenser 37 in the latest executed production cycle simulation, as the second lands 5B to which the solder PB is supplied via the dispenser 37 in practice. Similarly, the operator determines the lands 5 temporarily determined as the targets for the operation of the screen printing apparatus M2, as the first lands 5A to which the solder PA is supplied via the screen printing in practice.

The evaluation criteria in step S14 may change from productivity to quality. When printing quality takes precedence over productivity, the operator can determine that there is no problem even though the operation time of the solder coating apparatus M3 becomes a bottleneck.

Subsequently, the operator places an order for the mask plate 22 based the determined first lands 5A, and a mask is manufactured (ST17: mask manufacturing step). That is, a mask, which is provided with the mask plate 22 in which the pattern holes 22a are positioned so as to correspond to the first lands 5A, is manufactured. The manufactured mask plate 22 is used to produce the mounted board in the following step.

The operator prepares a dispenser coating program that causes the dispenser 37 to supply the solder PB, based on the determined second lands 5B (ST18: dispenser coating program preparation step). The prepared dispenser coating program is used to control the dispenser 37 of the solder coating apparatus M3 when producing the mounted board in the following step.

It is possible to adjust operation times between the screen printing apparatus M2 and the solder coating apparatus M3, and improve the productivity of the mounted board by sorting the first lands 5A and the second lands 5B by the above-mentioned method.

The present invention is not limited to the embodiment described so far, and modifications may be made to the design insofar as the modifications do not depart from the scope of the present invention. For example, the component mounting line may include the screen printing apparatus M2, the solder coating apparatus M3, and the electronic component mounting apparatuses M4 and M5. The types or number of other component mounting apparatuses incorporated into the component mounting line are arbitrarily determined. The number of electronic component mounting apparatuses M4 and M5 is also arbitrarily determined. In the solder coating apparatus M3, a plurality of the X-axis tables 35 may be installed on the Y-axis table 33, and the dispenser 37 may be attached to each of the X-axis tables 35, and a plurality of the dispensers 37 may supply the solder PB to a piece of the board 4.

According to the present invention, it is possible to mount electronic components on a board at high density and with high quality. The present invention is particularly useful in the electronic component mounting field.

What is claimed is:

1. An electronic component mounting method of using a solder paste to mount electronic components on a plurality of lands provided on a board, the method comprising:
supplying the solder paste to a plurality of first lands via screen printing among the plurality of lands, using a mask plate including pattern holes formed so as to correspond to the plurality of first lands;
supplying the solder paste to a plurality of second lands other than the first lands among the plurality of lands, using a coating unit provided with a discharge port for discharging the solder paste; and
mounting the electronic components on the first and second lands to which the solder paste is supplied.

2. The electronic component mounting method according to claim 1, wherein
the first lands and the second lands are sorted based on their land areas.

3. The electronic component mounting method according to claim 1, wherein
the first lands are selected from lands which have relatively large areas among the plurality of lands.

4. An electronic component mounting system of using a solder paste to mount electronic components on a plurality of lands provided on a board, the system comprising:
a screen printing apparatus that supplies the solder paste to a plurality of first lands among the plurality of lands, using a mask plate including pattern holes formed so as to correspond to the plurality of first lands;
a coating unit which includes a discharge port for discharging the solder paste, and coats the solder paste through the discharge port on a plurality of second lands other than the plurality of first lands on the board to which the solder paste is supplied through the screen printing apparatus; and
an electronic component mounting apparatus that mounts the electronic components on the first and second lands to which the solder paste is supplied through the screen printing apparatus and the coating unit.

5. The electronic component mounting system according to claim 4, wherein
the coating unit is disposed in the electronic component mounting apparatus.

6. The electronic component mounting system according to claim 4, wherein
the screen printing apparatus supplies the solder paste on the first lands which have relatively large areas among the plurality of lands.
